(19) United States
(12) Patent Application Publication
(10) Pub. No.: US 2003/0124861 A1
(43) Pub. Date: Jul. 3, 2003

(54) Method for manufacturing metal line contact plug semiconductor device

(76) Inventors: Pan Ki Kwon, Kyoungki-do (KR); Sang Ick Lee, Kyoungki-do (KR)

Correspondence Address: MARSHALL, GERSTEIN & BORUN, 6300 SEARS TOWER, 233 SOUTH WACKER, CHICAGO, IL, 60606-6357, US

(21) Appl. No.: 10/329,847

(22) Filed: Dec. 26, 2002

(30) Foreign Application Priority Data
Dec. 28, 2001 (KR) 2001-86843

(51) Int. Cl. C09K 13/00; H01L 21/461

(52) U.S. Cl. 438/692; 252/79.1; 438/697

(57) ABSTRACT

A chemical mechanical polishing (CMP) slurry for applying onto a complex structure consisting of two or more among a metal film, a nitride film and an oxide film and a method for manufacturing a metal line contact plug of a semiconductor device using the slurry. During a CMP process to form a metal line contact plug, an acidic CMP slurry having similar polishing speeds of metal films, oxide films and nitride films and not containing an oxidizer is used. As a result, a metal line contact plug can be easily separated using an acidic CMP slurry without any oxidizer.

### TECHNICAL FIELD

A chemical mechanical polishing (hereinafter, referred to as ‘CMP’) slurry for applying onto a complex structure consisting of two or more among a metal film, a nitride film and an oxide film is disclosed and a method for manufacturing a metal line contact plug of a semiconductor device is disclosed which uses the slurry. The disclosed technology easily separates a metal line contact plug by a CMP process using the CMP slurry which does not contain an oxidizer. A disclosed CMP process is performed using an acidic CMP slurry which polishes the polishing of a metal film, an oxide film and a nitride film at a similar speed. Generally, an oxidizer has been added to conventional CMP slurries for metal to improve the polishing speed. However, the disclosed slurry easily performs separation of a metal line contact plug by CMP process without adding any oxidizer into the disclosed CMP slurry.

### DESCRIPTION OF THE RELATED ART

Recently, device integration increases as improved integrated circuits are developed. For example, a device can comprise about 8,000,000 transistors per cm². As a result, a metal line of high quality which enables devices to be connected is required for high integration. Such complex structure lines can be embodied by efficiently planarizing dielectrics inserted between metal lines.

As a result, since a precise process of planarizing the wafer is required, CMP processes have been developed. During a CMP process, materials which need to be removed are chemically eliminated by using chemical materials which have good reactivity in CMP slurries. Simultaneously, the wafer surface is polished mechanically with ultrafine abrasives. A CMP process is performed by injecting a liquid slurry between the top surface of a wafer and a rotating elastic pad.

A conventional slurry used in a CMP process for metal comprises oxidizers such as H₂O₂, H₅IO₆ or FeNO₃; abrasives such as SiO₂, Al₂O₃ or MnO₂; dispersant; complexing agents; and buffers. When a metal is removed by a CMP process using the slurry, the metal surface is oxidized by the oxidizers, and then the oxidized portion is mechanically polished and removed by abrasives contained in the slurry.

Hereinafter, the conventional method for manufacturing a metal line contact plug of a semiconductor device will be explained with reference to the accompanying drawings.

FIG. 1a is a top plan view after forming a bit line pattern. FIG. 1b is a top plan view after etching a metal line contact plug. FIGS. 2a through 2d illustrate schematically conventional methods for manufacturing metal line contact plugs of semiconductor devices.

FIG. 2a is a diagram illustrating a condition wherein an interlayer insulating film is stacked on an A-A′ cross section of FIG. 1a. Bit lines 13 with mask insulating films 15 stacked thereon are formed on a semiconductor substrate 11. Here, the mask insulating films 15 are composed of nitride films with a thickness t1. Next, an interlayer insulating film 17 is formed on the entire surface of the resultant structure. The interlayer insulating film 17 is composed of an oxide film (see FIG. 2a).

FIG. 2b is a diagram illustrating a B-B′ cross section of FIG. 1b. A metal line contact hole 19 is formed by etching the interlayer insulating film 17 using a metal line contact mask as an etching mask. Here, a region “C” shown in FIG. 1b represents a region wherein the metal line contact hole 19 is formed by etching the interlayer insulating film 17 while a region “D” represents a region wherein the metal line contact hole 19 is not formed.

After depositing a predetermined thickness of an oxide film on the entire surface of the resultant structure, an oxide film spacers 21 are formed along the sidewalls of the metal line contact hole 19 and bit lines 13 are formed by blanket etching the deposited oxide film. Here, the thickness of the mask insulating films 15 on the bit lines 13 formed in the metal line contact hole 19 decreases to t2 due to etching processes to form the metal line contact hole 19 and to form the oxide film spacer 21 (see FIG. 2b).

Next, a metal film 23 is stacked on the entire surface of the resultant structure. Here, the metal film 23 has step coverage of t3 in the metal line contact hole 19 and of t4 from the mask insulating film 15 (see FIG. 2c).

A metal line contact plug 25 is formed by removing portions of the metal film 23, the interlayer insulating film 17 and the predetermined thickness of the mask insulating film 15 using a CMP process. Here, in order that the metal line contact plug 25 is separated into P1 and P2 using the CMP process, a depth of t4 should be polished using a slurry to remove portions of the metal film 23.

A polishing speed should be similar between films to remove the above complex structure. However, a polishing speed of metal films is over 20 times faster than that of oxide films when a CMP process is performed using conventional CMP slurry for metal to remove a metal. As a result, since a metal film of a low step coverage is not removed easily due to slow polishing speeds of oxide films or nitride films, a metal line contact plug is not separated (see FIG. 2d), and an equipment vibration phenomenon is generated, resulting in deteriorating stability of the process.

### SUMMARY OF THE DISCLOSURE

Accordingly, CMP slurries for applying onto a complex structure consisting of two or more among a metal film, a nitride film and an oxide film are disclosed and methods for manufacturing a metal line contact plug of a semiconductor device using the same are disclosed in which a metal line contact plug is easily separated, thereby improving stability of the manufacturing process.

### BRIEF DESCRIPTION OF THE DRAWINGS

The disclosed CMP slurries and manufacturing methods will become better understood with reference to the accompanying drawings which are provided only by way of illustration and thus are not limitative of this disclosure, wherein:

FIG. 1a is a top plan view after formation of a bit line pattern;

FIG. 1b is a top plan view after etching of a metal line contact plug;

FIGS. 2a through 2d illustrate, schematically, conventional methods of manufacturing metal line contact plugs of semiconductor devices; and

FIGS. 3a through 3d illustrate, schematically, disclosed methods for manufacturing metal line contact plugs of semiconductor devices in accordance with this disclosure.

### DETAILED DESCRIPTION OF THE PRESENTLY PREFERRED EMBODIMENTS

CMP slurries for applying onto a complex structure consisting of two or more among a metal film, a nitride film and an oxide film and methods for manufacturing a metal line contact plug of a semiconductor device which easily perform separation of a metal line contact plug without an oxidizer are disclosed which results in improved metal polishing speeds. Here, during a CMP process to form a metal line contact plug, acidic CMP slurries in which polishing speeds of metal films, oxide films and nitride films are similar is used.

The CMP slurry of the present disclosure is a slurry solution having a pH ranging from 2 to 4 which comprises water and an abrasive and not containing an oxidizer.

Here, the abrasive is selected from the group consisting of SiO₂, CeO₂, Mn₂O₃, ZrO₂, Al₂O₃ and mixtures thereof and is used in an amount ranging from about 10 to about 30% by weight of the CMP slurry.

The pH of the CMP slurry is controlled by a pH control agent selected from the group consisting of HNO₃, H₂SO₄, HCl, H₃PO₄, and mixtures thereof.

The CMP slurry has a polishing selectivity of 1:1˜2:1˜3 and preferably the similar polishing selectivity of 1:1:1 for a metal film:nitride film:oxide film. When the polishing selectivity is 1:1:1 for a metal film:nitride film:oxide film, the slurry has a pH ranging from 2 to 3.

In a CMP slurry for metal according to this disclosure, dispersant or buffers can be included.

As mentioned above, the CMP slurry according to the disclosure can polish metal without any oxidizer effectively since the pH of the slurry ranges from about 2 to about 4. That is, an abundance of hydrogen ion (H⁺) in the slurry weakens bonding forces between metals, atoms or components, and then abrasives in the slurry polish the weakened metal film, thereby removing the metal film with increased efficiency.

The CMP slurry of the present disclosure is useful for a CMP process performed on the complex structure consisting of two or more among a metal film, a nitride film and an oxide film.

Methods for manufacturing a metal line contact plug of a semiconductor device, comprise: forming a stack pattern of a bit line and a mask insulating film on a semiconductor substrate; forming an interlayer insulating film on the entire surface of the resultant structure; forming a metal line contact hole by defining the metal line contact hole region and selectively etching the interlayer insulating film to expose the semiconductor substrate and the stack patterns present in the contact hole region; forming an oxide film on the entire surface of the resultant structure; forming an oxide film spacer on the sidewalls of the metal line contact hole and stack patterns in the metal line contact hole by blanket etching the oxide film; depositing a metal film on the entire surface of the resultant structure; and performing a CMP process onto the entire surface of the resultant structure using a CMP slurry as disclosed above until exposing the mask insulating film of the stack pattern to form a metal line contact plug contact to the semiconductor substrate.

Methods for manufacturing a metal line contact plug of a semiconductor device in accordance with preferred embodiments will be described in detail with reference to the accompanying drawings.

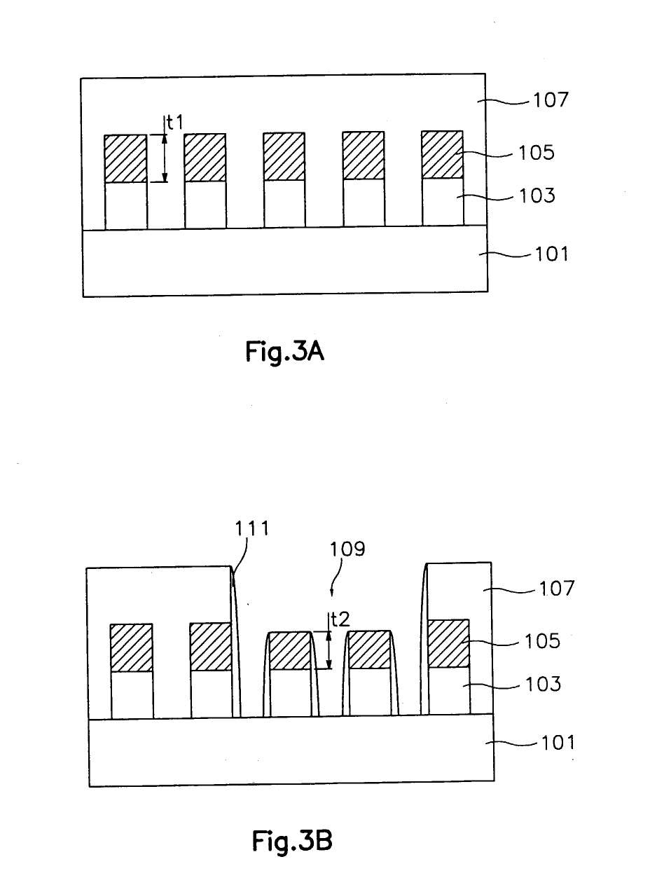

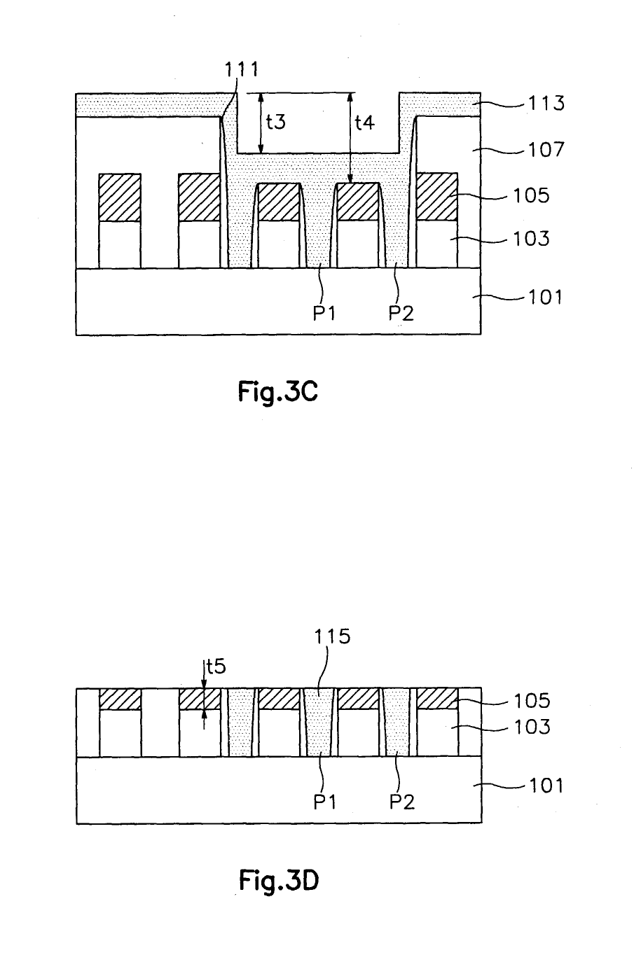

FIGS. 3a through 3d illustrate methods for manufacturing a metal line contact plug of semiconductor devices using the acidic CMP slurries disclosed herein.

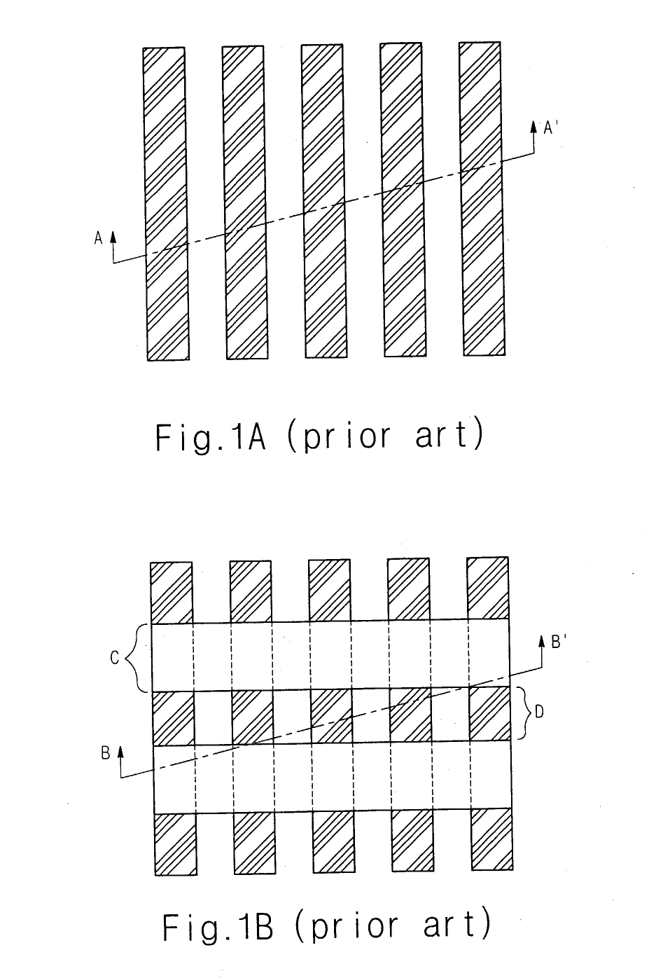

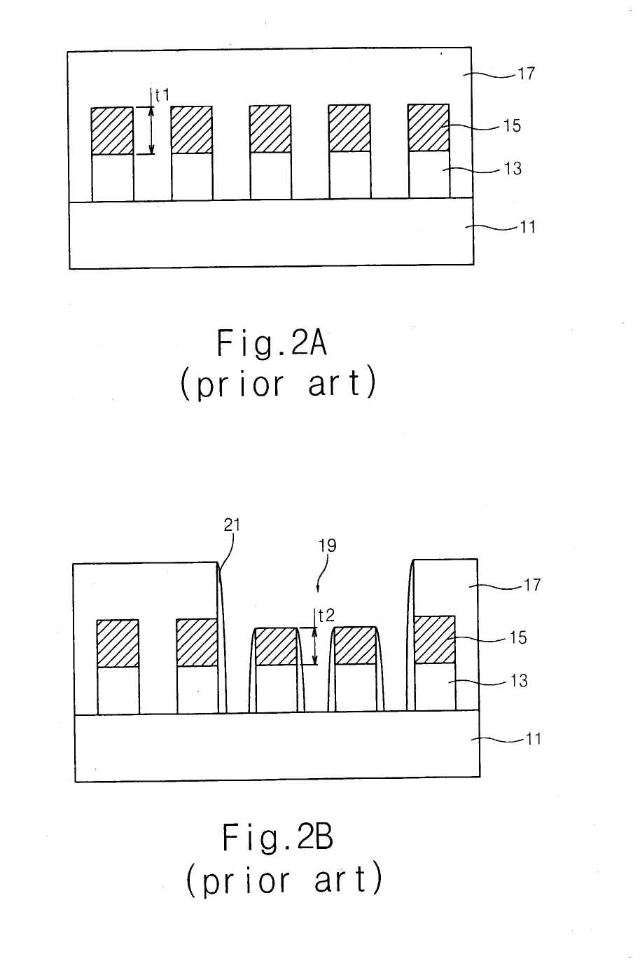

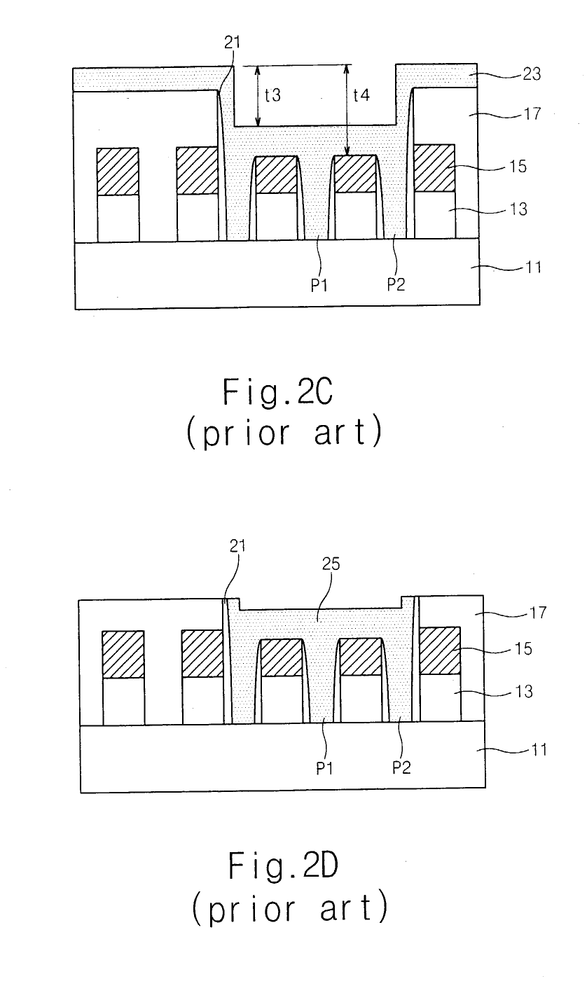

FIG. 3a is a diagram illustrating a condition wherein an interlayer insulating film is stacked on an A-A′ cross section of FIG. 1a. Bit lines 103 whereon mask insulating patterns 105 are stacked are formed on a semiconductor substrate 101. Here, the bit lines 103 are formed of tungsten, and Ti/TiN films as a diffusion barrier film disposed on the lower portion of the bit lines 103 (not shown). The Ti/TiN films are formed by a chemical vapor deposition method using TiCl₄ as a source.

The mask insulating films 105 are formed of a nitride film at a temperature ranging from about 500 to about 600° C. by a plasma chemical deposition method, and at its thickness of t1.

Next, an interlayer insulating film 107 is formed on the entire surface of the resultant structure. Here, the interlayer insulating film 107 is formed of an oxide film (see FIG. 3a).

FIG. 3b is a B-B′ cross section of FIG. 1b. A metal line contact hole 109 is formed by etching the interlayer insulating film 107 using a metal line contact mask as an etching mask.

Next, an oxide film spacer 111 is formed at sidewalls of the metal line contact hole 109 and the bit lines 103 by depositing a predetermined thickness of oxide film on the entire surface and then blanket etching it. Here, the thickness of the mask insulating film 105 on the bit line 103 formed in the metal line contact hole 109 decreases to t2 due to the etching processes to form the metal line contact hole 109 and to form the oxide film spacer 111 (see FIG. 3b).

Thereafter, a metal film 113 is deposited on the entire surface. Here, the metal film 113 consisting of TiN is deposited using an atomic layer deposition method has step coverage of t3 in the metal line contact hole 109 and of t4 from the mask insulating pattern 105 (see FIG. 3c). Since TiN has excellent activity, it can be easily polished by a slurry of the disclosure. The slurry of the disclosure can be used during a metal line process using W or Al other than TiN.

A CMP process is performed on the metal film 113, the interlayer insulating film 107 and the predetermined thickness of the mask insulating films 105, using a disclosed acidic CMP slurry. As a result, a metal line contact plug 115 in which a region P1 and a region P2 are separated and formed (see FIG. 3d).

Since the mask insulating film 105, the interlayer insulating film 107 and the metal film 113 are polished at a thickness of more than t4 using the CMP process, a thickness of the mask insulating films 105 on the bit lines 103 decrease to t5 smaller than t2.

If a CMP process is performed using a disclosed CMP slurry, a metal line contact plug is completely separated because a metal film having a low step coverage is sufficiently removed although the CMP slurry does not contain an oxidizer.

As discussed earlier, a complex structure can be planarized by a CMP process using a disclosed CMP slurry which does not contain an oxidizer. When a CMP process is performed on a complex structure including a metal film using a general CMP slurry for metal, the general CMP slurry for metal is five to ten times more expensive than a conventional CMP slurry for oxide. However, the disclosed slurry is as expensive as the CMP slurry for oxide, thereby reducing the economic cost effectively.

Additionally, a metal film, a nitride film and an oxide film can be removed by a one-step CMP process without performing a multi-step CMP process using different kinds of slurries, thereby reducing the process cost and improving reliability.

What is claimed is:

1. An oxidizer-free chemical mechanical polishing (CMP) slurry for applying onto a complex structure consisting of two or more among a metal film, a nitride film and an oxide film, comprising water and an abrasive and having a pH ranging from 2 to 4.

2. The CMP slurry according to claim 1, wherein the abrasive is present in an amount ranging from 10 to 30% by weight of the CMP slurry.

3. The CMP slurry according to claim 1, wherein the CMP slurry has a polishing selectivity of 1:1˜2:1˜3 for a metal film:nitride film:oxide film.

4. The CMP slurry according to claim 1, wherein the CMP slurry has a polishing selectivity of substantially 1:1:1 for a metal film:nitride film:oxide film.

5. The CMP slurry according to claim 4, wherein the slurry has a pH ranging from 2 to 3.

6. The CMP slurry according to claim 1, the slurry further comprising a pH control agent selected from the group consisting of HNO₃, H₂SO₄, HCl, H₃PO₄, and mixtures thereof.

7. The CMP slurry according to claim 1, wherein the abrasive is selected from the group consisting of SiO₂, CeO₂, Mn₂O₃, ZrO₂, Al₂O₃ and mixtures thereof.

8. A method for manufacturing a metal line contact plug of a semiconductor device, comprising:
(a) preparing a semiconductor substrate having a complex structure; and
(b) performing a CMP process onto the complex structure using a CMP slurry of claim 1.

9. The method according to claim 8, wherein the complex structure consists of two or more selected from the group consisting of a metal film, a nitride film and an oxide film.

10. The method according to claim 8, wherein the complex structure consists of a metal film, a nitride film and an oxide film.

11. A method for manufacturing a metal line contact plug of a semiconductor device, comprising:
(a) forming a stack pattern of a bit line and a mask insulating film on a semiconductor substrate;
(b) forming an interlayer insulating film on the entire surface of the resultant structure;
(c) forming a metal line contact hole by defining the metal line contact hole region and selectively etching the interlayer insulating film to expose the semiconductor substrate and the stack patterns present in the contact hole region;
(d) depositing a metal film on the entire surface of the resultant structure; and
(e) performing a CMP process onto the entire surface of the resultant structure using a CMP slurry of claim 1 until exposing the mask insulating film of the stack pattern to form a metal line contact plug contact to the semiconductor substrate.

12. The method according to claim 11, further comprising forming an oxide film spacer on the sidewalls of the metal line contact hole and stack patterns in the metal line contact hole.

13. The method according to claim 11, wherein the mask insulating film is a nitride film.

14. The method according to claim 11, wherein the interlayer insulating film is oxide film.

15. The method according to claim 11, wherein the metal film is the TiN film formed by atomic layer deposition.
